(19) United States
(12) Patent Application Publication
(10) Pub. No.: US 2020/0091955 A1
(43) Pub. Date: Mar. 19, 2020

(54) SECOND-ORDER HARMONIC REDUCTION FOR RADIO FREQUENCY TRANSMITTER

(71) Applicant: QUALCOMM Incorporated, San Diego, CA (US)

(72) Inventors: Cheng-Han WANG, San Jose, CA (US); Yi ZENG, San Jose, CA (US)

(21) Appl. No.: 16/130,745

(22) Filed: Sep. 13, 2018

(51) Int. Cl. H04B 1/48; H03F 1/56; H03F 3/189; H04B 1/18; H01Q 5/378

(52) U.S. Cl. CPC H04B 1/48; H03F 1/56; H04B 2001/485; H04B 1/18; H01Q 5/378; H03F 3/189

(57) ABSTRACT

Certain aspects of the present disclosure provide methods and apparatus for simultaneous multi-band transmission, including techniques and circuitry for reducing the coupling of a second-order harmonic signal into a victim circuit. One example radio frequency front-end circuit generally includes a first transmit output stage circuit configured to output signals in a first frequency band and a second transmit output stage circuit configured to output signals in a second frequency band. The first transmit output stage circuit generally includes a first adjustable transconductance stage comprising an input stage and a cascode stage coupled to the input stage; and a first adjustable impedance stage coupled to the first adjustable transconductance stage. For certain aspects, the second transmit output stage circuit generally includes a second adjustable transconductance stage and a second adjustable impedance stage coupled to the second adjustable transconductance stage.

### TECHNICAL FIELD

Certain aspects of the present disclosure generally relate to electronic circuits and, more particularly, to a radio frequency front-end circuit for simultaneous multi-band transmission, including techniques and circuitry for reducing the coupling of a second-order harmonic signal into a victim circuit.

### BACKGROUND

Wireless communication networks are widely deployed to provide various communication services such as telephony, video, data, messaging, broadcasts, and so on. Such networks, which are usually multiple access networks, support communications for multiple users by sharing the available network resources. For example, one network may be a 3G (the third generation of mobile phone standards and technology), 4G, 5G, or later system, which may provide network service via any one of various radio access technologies (RATs) including EVDO (Evolution-Data Optimized), 1xRTT (1 times Radio Transmission Technology, or simply 1x), W-CDMA (Wideband Code Division Multiple Access), UMTS-TDD (Universal Mobile Telecommunications System—Time Division Duplexing), HSPA (High Speed Packet Access), GPRS (General Packet Radio Service), or EDGE (Enhanced Data rates for Global Evolution). Such multiple access networks may also include code division multiple access (CDMA) systems, time division multiple access (TDMA) systems, frequency division multiple access (FDMA) systems, orthogonal frequency division multiple access (OFDMA) systems, single-carrier FDMA (SC-FDMA) networks, 3^{rd} Generation Partnership Project (3GPP) Long Term Evolution (LTE) networks, and Long Term Evolution Advanced (LTE-A) networks. Other examples of wireless communication networks may include WiFi (in accordance with IEEE 802.11), WiMAX (in accordance with IEEE 802.16), and Bluetooth® networks.

A wireless communication network may include a number of base stations that can support communication for a number of mobile stations. A mobile station (MS) may communicate with a base station (BS) via a downlink and an uplink. The downlink (or forward link) refers to the communication link from the base station to the mobile station, and the uplink (or reverse link) refers to the communication link from the mobile station to the base station. A base station may transmit data and control information on the downlink to a mobile station and/or may receive data and control information on the uplink from the mobile station.

In some cases, a base station or a mobile station may offer simultaneous multi-band capability, such as support for dual-band simultaneous (DBS). Also known as simultaneous dual band, DBS allows for concurrent transmission in two different frequency bands and/or wireless protocols. In WiFi, for example, the two frequency bands may be 2.4 GHz and 5.0 GHz. Radio frequency front-ends supporting DBS may be implemented with two transmission paths for concurrent transmission.

### SUMMARY

Certain aspects of the present disclosure generally relate to methods and apparatus for simultaneous multi-band transmission, including techniques and circuitry for reducing the coupling of a second-order harmonic signal into a victim circuit.

Certain aspects of the present disclosure provide a radio frequency front-end (RFFE) circuit. The RFFE circuit generally includes a first transmit output stage circuit configured to output signals in a first frequency band and a second transmit output stage circuit configured to output signals in a second frequency band. The first transmit output stage circuit generally includes a first adjustable transconductance stage comprising an input stage and a cascode stage coupled to the input stage, and a first adjustable impedance stage coupled to the first adjustable transconductance stage.

Certain aspects of the present disclosure provide a method of adjusting an RFFE circuit capable of simultaneous multi-band transmission. The method generally includes adjusting a transconductance of a first transmit output stage circuit in the RFFE circuit, the first transmit output stage circuit being configured to output signals in a first frequency band; and adjusting an impedance of the first transmit output stage circuit, wherein the RFFE circuit further comprises a second transmit output stage circuit configured to output signals in a second frequency band concurrently with the signals output by the first transmit output stage circuit.

Certain aspects of the present disclosure provide an apparatus for simultaneous multi-band transmission. The apparatus generally includes first means for outputting signals in a first frequency band comprising means for adjusting a transconductance of the first means for outputting signals and means for adjusting an impedance of the first means for outputting signals; and second means for outputting signals in a second frequency band concurrently with the signals output by the first means for outputting signals. For certain aspects, the second means for outputting signals includes at least one of means for adjusting a transconductance of the second means for outputting signals or means for adjusting an impedance of the second means for outputting signals.

### BRIEF DESCRIPTION OF THE DRAWINGS

So that the manner in which the above-recited features of the present disclosure can be understood in detail, a more particular description, briefly summarized above, may be had by reference to aspects, some of which are illustrated in the appended drawings. It is to be noted, however, that the appended drawings illustrate only certain typical aspects of this disclosure and are therefore not to be considered limiting of its scope, for the description may admit to other equally effective aspects.

FIG. 1 is a diagram of an example wireless communications network, in accordance with certain aspects of the present disclosure.

FIG. 2 is a block diagram of an example access point (AP) and example user terminals, in accordance with certain aspects of the present disclosure.

FIG. 3 is a block diagram of an example transceiver/front end, in accordance with certain aspects of the present disclosure.

FIG. 4A is a block diagram of an example radio frequency front-end (RFFE) circuit with dual-band simultaneous (DBS) support, in accordance with certain aspects of the present disclosure.

FIG. 4B is a simplified block diagram of an example RFFE circuit with DBS support, in accordance with certain aspects of the present disclosure.

FIG. 5A is an example circuit model of transformer coupling between a transmit output stage circuit and an antenna, in accordance with certain aspects of the present disclosure.

FIG. 5B is an example circuit model of electromagnetic coupling between an aggressor transmit output stage circuit and a victim circuit, in accordance with certain aspects of the present disclosure.

FIG. 5C is an example circuit model of adjusting current and impedance in the victim circuit of FIG. 5B, in accordance with certain aspects of the present disclosure.

FIG. 6A is a system of equations for the circuit model of FIG. 5A, in accordance with certain aspects of the present disclosure.

FIG. 6B illustrates the system of equations of FIG. 6A rewritten in terms of the currents through the primary coil, in accordance with certain aspects of the present disclosure.

FIG. 6C illustrates an equation for the voltage in the secondary coil, based on the equations of FIG. 6B, in accordance with certain aspects of the present disclosure.

FIG. 7A illustrates a solution for the equations of FIG. 6C in terms of a change in current, in accordance with certain aspects of the present disclosure.

FIG. 7B illustrates a solution for the equations of FIG. 6C in terms of a change in impedance, in accordance with certain aspects of the present disclosure.

FIG. 8A is a schematic diagram of an example transmit output stage circuit capable of current and/or impedance adjustment for implementing the RFFE circuit of FIG. 4B, in accordance with certain aspects of the present disclosure.

FIG. 8B is an example implementation of the transmit output stage circuit of FIG. 8A using a variable number of transconductance slices, in accordance with certain aspects of the present disclosure.

FIG. 8C is an example implementation of the transmit output stage circuit of FIG. 8A using a variable bias circuit, in accordance with certain aspects of the present disclosure.

FIG. 9 is a flow diagram of example operations for calibrating an RFFE circuit supporting simultaneous multi-band transmission, in accordance with certain aspects of the present disclosure.

FIG. 10 is a flow diagram of example operations for adjusting an RFFE circuit capable of simultaneous multi-band transmission, in accordance with certain aspects of the present disclosure.

### DETAILED DESCRIPTION

Certain aspects of the present disclosure provide a radio frequency front-end (RFFE) circuit for simultaneous multi-band transmission, such as an RFFE circuit with support for dual-band simultaneous (DBS). The RFFE circuit may include at least one transmit output stage circuit capable of adjusting a current (e.g., by adjusting a transconductance) and/or an impedance therein, in an effort to reduce the coupling of a second-order harmonic signal into a victim circuit, such as another transmit output stage circuit or a receive input circuit, as described in more detail below.

Various aspects of the disclosure are described more fully hereinafter with reference to the accompanying drawings. This disclosure may, however, be embodied in many different forms and should not be construed as limited to any specific structure or function presented throughout this disclosure. Rather, these aspects are provided so that this disclosure will be thorough and complete, and will fully convey the scope of the disclosure to those skilled in the art. Based on the teachings herein one skilled in the art should appreciate that the scope of the disclosure is intended to cover any aspect of the disclosure disclosed herein, whether implemented independently of or combined with any other aspect of the disclosure. For example, an apparatus may be implemented or a method may be practiced using any number of the aspects set forth herein. In addition, the scope of the disclosure is intended to cover such an apparatus or method which is practiced using other structure, functionality, or structure and functionality in addition to or other than the various aspects of the disclosure set forth herein. It should be understood that any aspect of the disclosure disclosed herein may be embodied by one or more elements of a claim.

The word “exemplary” is used herein to mean “serving as an example, instance, or illustration.” Any aspect described herein as “exemplary” is not necessarily to be construed as preferred or advantageous over other aspects.

As used herein, the term “connected with” in the various tenses of the verb “connect” may mean that element A is directly connected to element B or that other elements may be connected between elements A and B (i.e., that element A is indirectly connected with element B) . In the case of electrical components, the term “connected with” may also be used herein to mean that a wire, trace, or other electrically conductive material is used to electrically connect elements A and B (and any components electrically connected therebetween).

The techniques described herein may be used in combination with various wireless technologies such as Code Division Multiple Access (CDMA), Orthogonal Frequency Division Multiplexing (OFDM), Time Division Multiple Access (TDMA), Spatial Division Multiple Access (SDMA), Single Carrier Frequency Division Multiple Access (SC-FDMA), Time Division Synchronous Code Division Multiple Access (TD-SCDMA), Time Division Synchronous Code Division Multiple Access (TD-SCDMA), and so on. Multiple user terminals can concurrently transmit/receive data via different (1) orthogonal code channels for CDMA, (2) time slots for TDMA, or (3) sub-bands for OFDM. A CDMA system may implement IS-2000, IS-95, IS-856, Wideband-CDMA (W-CDMA), or some other standards. An OFDM system may implement Institute of Electrical and Electronics Engineers (IEEE) 802.11, IEEE 802.16, Long Term Evolution (LTE) (e.g., in TDD and/or FDD modes), or some other standards. A TDMA system may implement Global System for Mobile Communications (GSM) or some other standards.

### An Example Wireless System

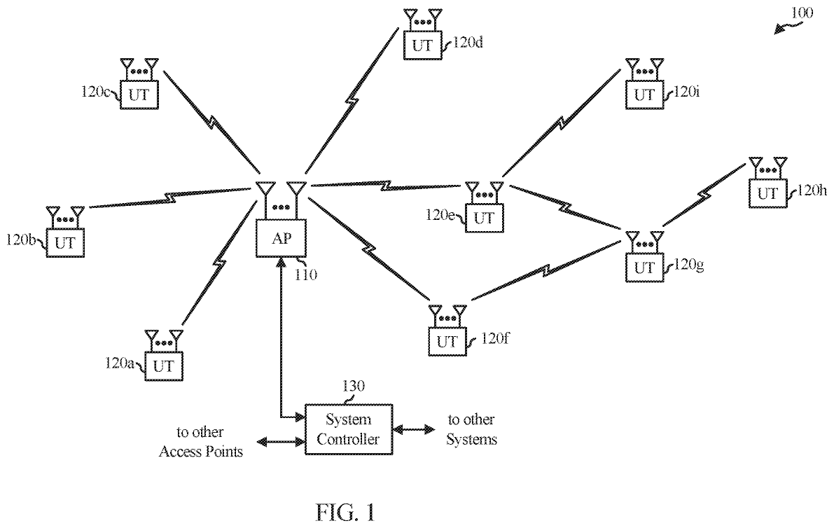

FIG. 1 illustrates a wireless communications system 100 with access points 110 and user terminals 120, in which aspects of the present disclosure may be practiced. For simplicity, only one access point 110 is shown in FIG. 1. An access point (AP) is generally a fixed station that communicates with the user terminals and may also be referred to as a base station (BS), an evolved Node B (eNB), or some other terminology. A user terminal (UT) may be fixed or mobile and may also be referred to as a mobile station (MS), an access terminal, user equipment (UE), a station (STA), a client, a wireless device, or some other terminology. A user terminal may be a wireless device, such as a cellular phone, a personal digital assistant (PDA), a handheld device, a wireless modem, a laptop computer, a tablet, a personal computer, etc.

Access point 110 may communicate with one or more user terminals 120 at any given moment on the downlink and uplink. The downlink (i.e., forward link) is the communication link from the access point to the user terminals, and the uplink (i.e., reverse link) is the communication link from the user terminals to the access point. A user terminal may also communicate peer-to-peer with another user terminal. A system controller 130 couples to and provides coordination and control for the access points.

System 100 employs multiple transmit and multiple receive antennas for data transmission on the downlink and uplink. Access point 110 may be equipped with a number Nₐₚ of antennas to achieve transmit diversity for downlink transmissions and/or receive diversity for uplink transmissions. A set Nᵤ of selected user terminals 120 may receive downlink transmissions and transmit uplink transmissions. Each selected user terminal transmits user-specific data to and/or receives user-specific data from the access point. In general, each selected user terminal may be equipped with one or multiple antennas (i.e., Nᵤₜ≥1). The Nᵤ selected user terminals can have the same or different number of antennas.

Wireless system 100 may be a time division duplex (TDD) system or a frequency division duplex (FDD) system. For a TDD system, the downlink and uplink share the same frequency band. For an FDD system, the downlink and uplink use different frequency bands. System 100 may also utilize a single carrier or multiple carriers for transmission. Each user terminal 120 may be equipped with a single antenna (e.g., in order to keep costs down) or multiple antennas (e.g., where the additional cost can be supported).

The access point 110 and/or user terminal 120 may include a radio frequency front-end (RFFE) circuit for simultaneous multi-band transmission, such as an RFFE circuit with support for dual-band simultaneous (DBS). The RFFE circuit may include at least one transmit output stage circuit capable of adjusting a current (e.g., by adjusting a transconductance) and/or an impedance therein, in an effort to reduce the coupling of a second-order harmonic signal into a victim circuit, such as another transmit output stage circuit or a receive input circuit, as described in more detail below.

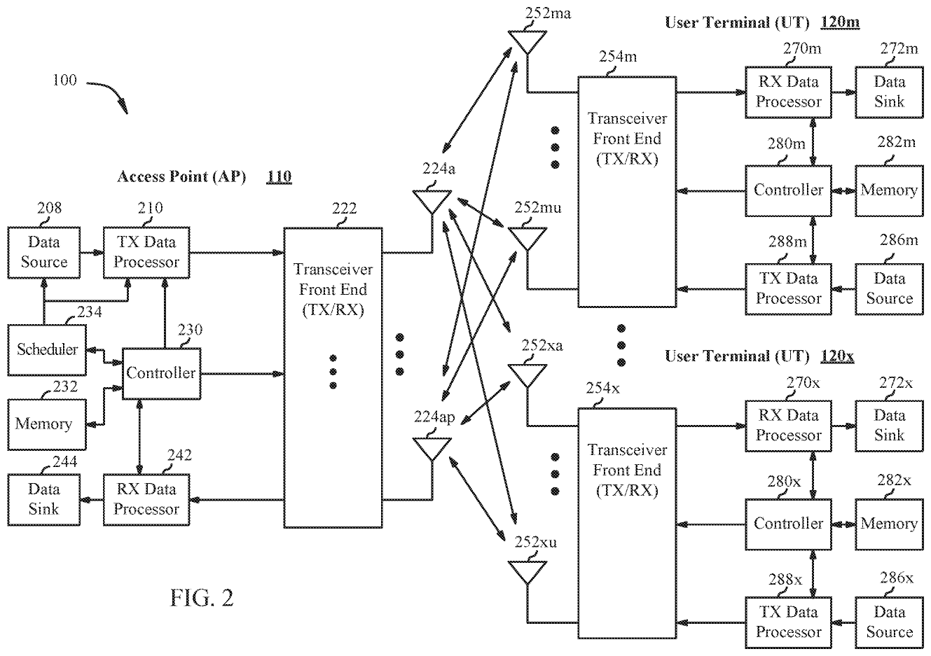

FIG. 2 shows a block diagram of access point 110 and two user terminals 120m and 120x in wireless system 100. For certain aspects, the access point 110 is instead implemented as a base station, and/or one or more of the user terminals 120 are instead implemented as one or more mobile stations. Access point 110 is equipped with Nₐₚ antennas 224a through 224ap. User terminal 120m is equipped with N_{ut,m} antennas 252ma through 252mu, and user terminal 120x is equipped with N_{ut,x} antennas 252xa through 252xu. Access point 110 is a transmitting entity for the downlink and a receiving entity for the uplink. Each user terminal 120 is a transmitting entity for the uplink and a receiving entity for the downlink. As used herein, a “transmitting entity” is an independently operated apparatus or device capable of transmitting data via a frequency channel, and a “receiving entity” is an independently operated apparatus or device capable of receiving data via a frequency channel. In the following description, the subscript “dn” denotes the downlink, the subscript “up” denotes the uplink, Nᵤₚ user terminals may be selected for simultaneous transmission on the uplink, N_{dn} user terminals may be selected for simultaneous transmission on the downlink, Nᵤₚ may or may not be equal to N_{dn}, and Nᵤₚ and N_{dn} may be static values or can change for each scheduling interval. Beam-steering or some other spatial processing technique may be used at the access point, base station, mobile station, and/or user terminal.

On the uplink, at each user terminal 120 selected for uplink transmission, a TX data processor 288 receives traffic data from a data source 286 and control data from a controller 280. TX data processor 288 processes (e.g., encodes, interleaves, and modulates) the traffic data {dᵤₚ} for the user terminal based on the coding and modulation schemes associated with the rate selected for the user terminal and provides a data symbol stream {sᵤₚ}for one of the N_{ut,m} antennas. A transceiver/front end (TX/RX) 254 (also known as a radio frequency front end (RFFE)) receives and processes (e.g., converts to analog, amplifies, filters, and frequency upconverts) a respective symbol stream to generate an uplink signal. The transceiver/front end 254 may also route the uplink signal to one of the N_{ut,m} antennas for transmit diversity via an RF switch, for example. The controller 280 may control the routing within the transceiver/front end 254. Memory 282 may store data and program codes for the user terminal 120 and may interface with the controller 280.

A number Nᵤₚ of user terminals 120 may be scheduled for simultaneous transmission on the uplink. Each of these user terminals transmits its set of processed symbol streams on the uplink to the access point.

At access point 110, Nₐₚ antennas 224a through 224ap receive the uplink signals from all Nᵤₚ user terminals transmitting on the uplink. For receive diversity, a transceiver/front end 222 may select signals received from one of the antennas 224 for processing. The signals received from multiple antennas 224 may be combined for enhanced receive diversity. The access point's transceiver/front end 222 also performs processing complementary to that performed by the user terminal's transceiver/front end 254 and provides a recovered uplink data symbol stream. The recovered uplink data symbol stream is an estimate of a data symbol stream {sᵤₚ} transmitted by a user terminal. An RX data processor 242 processes (e.g., demodulates, deinterleaves, and decodes) the recovered uplink data symbol stream in accordance with the rate used for that stream to obtain decoded data. The decoded data for each user terminal may be provided to a data sink 244 for storage and/or a controller 230 for further processing.

While FIG. 2 illustrates the transceiver/front ends 222, 254 each in a single box, those of skill in the art will appreciate that elements of the transceiver/front ends 222, 254 may be implemented across various elements, chips, modules, etc. For example, down and/or upconversion elements may be included in a transceiver chip within the transceiver/front end 222, 254, while a power amplifier and/or envelope tracking elements may be implemented in a module separate from the transceiver chip within the transceiver/front end 222, 254.

The transceiver/front end (TX/RX) 222 of access point 110 and/or the TX/RX 254 of user terminal 120 may include an RFFE circuit for simultaneous multi-band transmission, such as an RFFE circuit with DBS support. As described in more detail below, the RFFE circuit may include at least one transmit output stage circuit capable of adjusting a current (e.g., by adjusting a transconductance) and/or an impedance therein, in an effort to reduce the coupling of a second-order harmonic signal into a victim circuit, such as another transmit output stage circuit or a receive input circuit.

On the downlink, at access point 110, a TX data processor 210 receives traffic data from a data source 208 for N_{dn} user terminals scheduled for downlink transmission, control data from a controller 230 and possibly other data from a scheduler 234. The various types of data may be sent on different transport channels. TX data processor 210 processes (e.g., encodes, interleaves, and modulates) the traffic data for each user terminal based on the rate selected for that user terminal. TX data processor 210 may provide a downlink data symbol stream for one or more of the N_{dn} user terminals to be transmitted from one of the Nₐₚ antennas. The transceiver/front end 222 receives and processes (e.g., converts to analog, amplifies, filters, and frequency upconverts) the symbol stream to generate a downlink signal. The transceiver/front end 222 may also route the downlink signal to one or more of the Nₐₚ antennas 224 for transmit diversity via an RF switch, for example. The controller 230 may control the routing within the transceiver/front end 222. Memory 232 may store data and program codes for the access point 110 and may interface with the controller 230.

At each user terminal 120, N_{ut,m} antennas 252 receive the downlink signals from access point 110. For receive diversity at the user terminal 120, the transceiver/front end 254 may select signals received from one of the antennas 252 for processing. The signals received from multiple antennas 252 may be combined for enhanced receive diversity. The user terminal's transceiver/front end 254 also performs processing complementary to that performed by the access point's transceiver/front end 222 and provides a recovered downlink data symbol stream. An RX data processor 270 processes (e.g., demodulates, deinterleaves, and decodes) the recovered downlink data symbol stream to obtain decoded data for the user terminal.

Those skilled in the art will recognize the techniques described herein may be generally applied in systems utilizing any type of multiple access schemes, such as TDMA, SDMA, Orthogonal Frequency Division Multiple Access (OFDMA), CDMA, SC-FDMA, TD-SCDMA, and combinations thereof, among other systems/schemes.

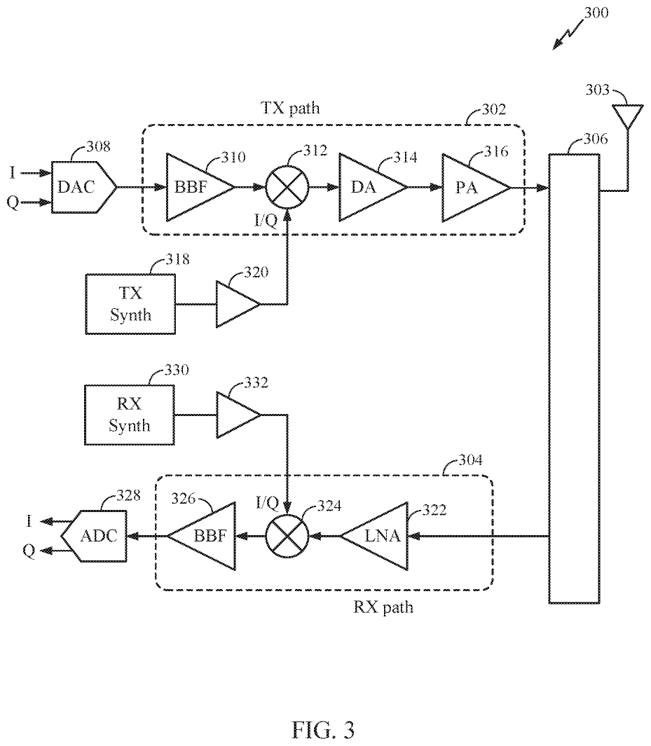

FIG. 3 is a block diagram of an example transceiver/front end 300, such as transceiver/front ends 222, 254 in FIG. 2, in which aspects of the present disclosure may be practiced. The transceiver/front end 300 includes a transmit (TX) path 302 (also known as a transmit chain) for transmitting signals via one or more antennas and a receive (RX) path 304 (also known as a receive chain) for receiving signals via the antennas. When the TX path 302 and the RX path 304 share an antenna 303, the paths may be connected with the antenna via an interface 306, which may include any of various suitable RF devices, such as a duplexer, a switch, a diplexer, and the like.

Receiving in-phase (I) and/or quadrature (Q) baseband analog signals from a digital-to-analog converter (DAC) 308, the TX path 302 may include a baseband filter (BBF) 310, a mixer 312, a driver amplifier (DA) 314, and a power amplifier (PA) 316. The BBF 310, the mixer 312, and the DA 314 may be included in a radio frequency integrated circuit (RFIC), while the PA 316 may be external to the RFIC. The BBF 310 filters the baseband signals received from the DAC 308, and the mixer 312 mixes the filtered baseband signals with a transmit local oscillator (LO) signal to convert the baseband signal of interest to a different frequency (e.g., upconvert from baseband to RF). This frequency conversion process produces the sum and difference frequencies of the LO frequency and the frequency of the signal of interest. The sum and difference frequencies are referred to as the beat frequencies. The beat frequencies are typically in the RF range, such that the signals output by the mixer 312 are typically RF signals, which are amplified by the DA 314 and by the PA 316 before transmission by the antenna 303.

The RX path 304 includes a low noise amplifier (LNA) 322, a mixer 324, and a baseband filter (BBF) 326. The LNA 322, the mixer 324, and the BBF 326 may be included in a radio frequency integrated circuit (RFIC), which may or may not be the same RFIC that includes the TX path components. RF signals received via the antenna 303 may be amplified by the LNA 322, and the mixer 324 mixes the amplified RF signals with a receive local oscillator (LO) signal to convert the RF signal of interest to a different baseband frequency (i.e., downconvert). The baseband signals output by the mixer 324 may be filtered by the BBF 326 before being converted by an analog-to-digital converter (ADC) 328 to digital I or Q signals for digital signal processing.

Tuning to different frequencies may implicate using a variable-frequency oscillator, which may involve compromises between stability and tunability. Contemporary systems may employ one or more frequency synthesizers with a voltage-controlled oscillator (VCO) to generate a stable, tunable LO with a particular tuning range. Thus, the transmit LO may be produced by a TX frequency synthesizer 318, whose output may be buffered or amplified by amplifier 320 before being mixed with the baseband signals in the mixer 312. Similarly, the receive LO may be produced by an RX frequency synthesizer 330, whose output may be buffered or amplified by amplifier 332 before being mixed with the RF signals in the mixer 324. For certain aspects, the function of the TX and RX frequency synthesizer may be performed by a single frequency synthesizer, producing an LO for both the transmit and the receive paths. The transceiver/front end 300 may, for example, be configured for operation in quadrature or polar.

According to certain aspects, the transceiver/front end 300 may include multiple transmit output stage circuits for simultaneous multi-band transmission (e.g., DBS). In this case, the transceiver/front end 300 may include at least one transmit output stage circuit capable of adjusting a current (e.g., by adjusting a transconductance) and/or an impedance therein, in an effort to reduce the coupling of a second-order harmonic signal into a victim circuit, such as another transmit output stage circuit or a receive input circuit (e.g., the LNA 322), as described in more detail below.

### An Example RF Front-End for Simultaneous Multi-Band Transmission

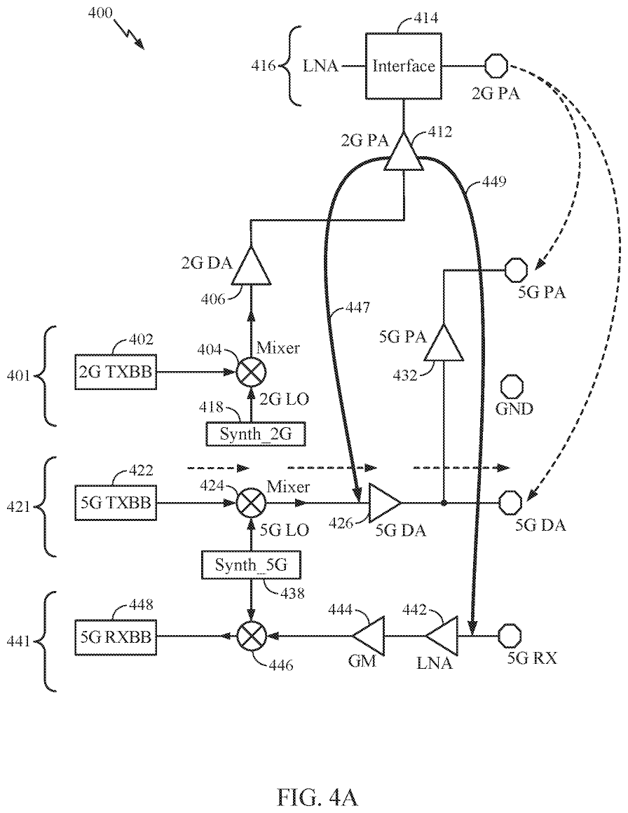

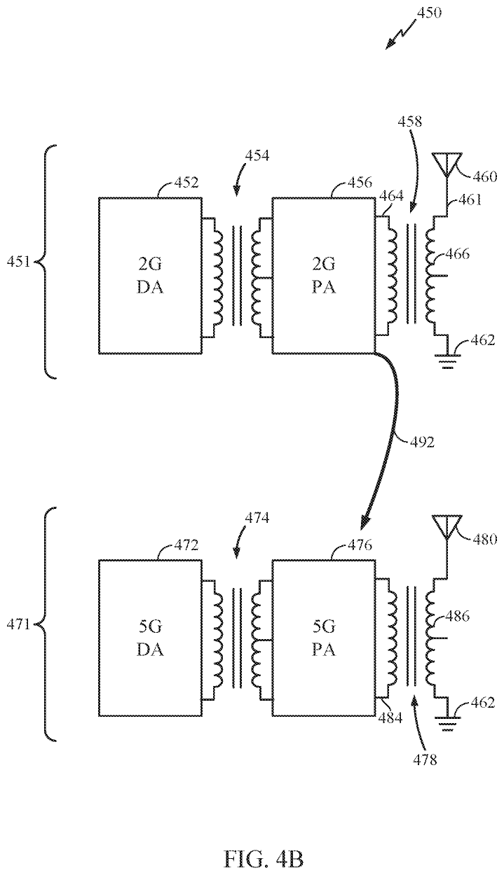

FIG. 4A is a block diagram of an example radio frequency front-end (RFFE) circuit 400 with dual-band simultaneous (DBS) support, in accordance with certain aspects of the present disclosure. Although the example RFFE circuit 400 provides DBS support for 2G and 5G transmissions, the reader will understand that this example may apply to other frequency bands or to more than two bands. For ease of description, the RFFE circuit 400 is described hereinafter as supporting concurrent 2G and 5G transmissions.

The RFFE circuit 400 includes a 2G transmit path 401, a 5G transmit path 421 (e.g., similar to TX path 302), and a 5G receive path 441 (e.g., similar to RX path 304). The 2G transmit path 401 includes 2G transmit baseband (TXBB) circuitry 402, a mixer 404 having an input coupled to an output of the 2G TXBB circuitry 402, a 2G driver amplifier (DA) 406 having an input coupled to an output of the mixer 404, a 2G power amplifier (PA) 412 having an input coupled to an output of the 2G DA 406 for outputting RF transmissions in the 2G frequency band, and an interface circuit 414 having an input coupled to an output of the 2G PA 412. The interface circuit 414 may be similar to interface 306 and may include any of various suitable RF devices, such as a duplexer, a switch, a diplexer, and the like. For example, the interface circuit 414 may include a switch for connecting a single antenna (not shown) between the output of the 2G transmit path 401 and an input of a 2G receive path 416 including a low noise amplifier (LNA). The 2G transmit path 401 may also include or be coupled to a frequency synthesizer 418 (labeled “Synth_2G”) for generating a 2G local oscillator (LO) signal (e.g., having a frequency of 2.4 GHz) for the 2G transmit path 401.

The 5G transmit path 421 includes 5G TXBB circuitry 422, a mixer 424 having an input coupled to an output of the 5G TXBB circuitry 422, a 5G DA 426 having an input coupled to an output of the mixer 424, and a 5G PA 432 having an input coupled to an output of the 5G DA 426 for outputting RF transmissions in the 5G frequency band. The 5G transmit path 421 may be coupled to a frequency synthesizer 438 (labeled “Synth_5G”) for generating a 5G LO signal (e.g., having a frequency of 5.1 GHz) for the 5G transmit path 421.

The 5G receive path 441 includes a low noise amplifier (LNA) 442, a transconductance (GM) amplifier 444 having an input coupled to an output of the LNA 442, a mixer 446 having an input coupled to an output of the transconductance amplifier 444, and 5G receive baseband (RXBB) circuitry 448 having an input coupled to an output of the mixer 446. Another input of the mixer 446 may receive the 5G LO signal from the frequency synthesizer 438 as illustrated.

With DBS support, the RFFE circuit 400 is capable of simultaneously transmitting 2G and 5G RF signals. However, 2G signals from the 2G transmit path 401 may couple into the 5G transmit path 421 and/or the 5G receive path 441. For example, 2G signals output by the 2G PA 412 may couple into the input of the 5G DA 426, as illustrated by the arrow 447. As another example, 2G signals output by the 2G PA 412 may couple into the input of the 5G LNA 442, as illustrated by the arrow 449. The coupling mechanism may include inductive coupling and/or ground coupling. For certain frequency band combinations in DBS, frequencies outside of the frequency band of interest may be filtered out. However, in the case of 2.4 GHz and 5.1 GHz signals, the second harmonic of 2.4 GHz signals falls within the frequency band of interest for 5.1 GHz signals and cannot be easily rejected by a filter in the 5G transmit or receive path. This second harmonic component can lead to increased emissions in the 5G transmit path 421 and can cause the RFFE circuit 400 to fail certain specifications, such as the measured power density at an antenna output as set, for example, by the Federal Communications Commission (FCC) in the United States. Such coupling may get worse as the two transmit paths 401, 421 become closer, due to integrated circuit (IC) dies becoming smaller and smaller. Furthermore, this second harmonic component can cause sensitivity degradation in the 5G receive path 441.

FIG. 4B is a simplified block diagram of a portion of an example RFFE circuit 450 providing DBS support, in accordance with certain aspects of the present disclosure. The RFFE circuit 450 includes a first transmit path 451 associated with a first frequency band (e.g., 2G) and a second transmit path 471associated with a second frequency band (e.g., 5G). Although only portions of the first and second transmit paths 451, 471 are illustrated in the simplified block diagram of FIG. 4B, the reader will understand that the first and/or second transmit path may include additional circuitry, for example, as described for transmit paths 401, 421 in FIG. 4A.

The first transmit path 451 includes a driver amplifier (DA) 452 associated with the first frequency band (e.g., 2G, so labeled “2G DA”), a power amplifier (PA) 456 associated with the first frequency band (e.g., 2G, so labeled “2G PA”), and an antenna 460. Although a single PA 456 is illustrated in FIG. 4B, the transmit output stage circuit before the antenna 460 may additionally include a pre-amplifier or another power amplifier. The (differential) output of the DA 452 is inductively coupled to the (differential) input of the PA 456 via a transformer 454. The (differential) output of the PA 456 is inductively coupled to the antenna 460 via a transformer 458. As illustrated in FIG. 4B, the transformer 458 is implemented by a balun to convert the (differential) output of the PA 456 to a single-ended output signal at the antenna 460. The balun includes a primary coil 464 coupled to the output of the PA 456 and a secondary coil 466 coupled between the antenna 460 (or at least to a radio frequency signal node 461) and a reference potential node 462 (e.g., electrical ground) for the RFFE circuit 450. The RF signal node 461 may be included in an integrated circuit (IC) along with the 2G DA 452 and the 2G PA 456, whereas the antenna 460 may be external to this IC. Such an IC may provide a pin or other interface for the RF signal node 461 and/or the reference potential node 462.

The second transmit path 471 includes a DA 472 associated with the second frequency band (e.g., 5G, so labeled “5G DA”), a PA 476 associated with the second frequency band (e.g., 5G, so labeled “5G PA”), and an antenna 480. Although a DA in series with a PA 476 is illustrated in FIG. 4B, the transmit output stage circuit before the antenna 480 may alternatively include any of various suitable combinations of one or more driver amplifiers, power amplifiers, and/or pre-amplifiers. The (differential) output of the DA 472 is inductively coupled to the (differential) input of the PA 476 via a transformer 474. The (differential) output of the PA 476 is inductively coupled to the antenna 480 via a transformer 478. As illustrated in FIG. 4B, the transformer 478 is implemented by a balun to convert the (differential) output of the PA 476 to a single-ended output signal at the antenna 480. The balun includes a primary coil 484 coupled to the output of the PA 476 and a secondary coil 486 coupled between the antenna 480 and the reference potential node 462 for the RFFE circuit 450.

As illustrated by the arrow 492, signals from the first transmit path 451 may couple into the second transmit path 471. This coupling may occur electromagnetically (e.g., via inductive coupling between the transformers 458 and 478) and/or via ground coupling issues. As described above, if the second harmonic of signals from the first frequency band falls within the second frequency band, the second transmit path 471 may fall victim to the first transmit path 451 and exhibit increased emissions.

Accordingly, certain aspects of the present disclosure provide methods and apparatus for reducing the coupling of a second-order harmonic signal into a victim circuit in the case of simultaneous multi-band transmissions.

Theoretically, the second-order harmonic is a common-mode signal and, thus, may appear when there is an imbalance (e.g., due to non-idealities) in a differential circuit. By adjusting the imbalance, the amplitude of the second-order harmonic signal output by the aggressor circuit (and therefore appearing in the victim circuit) can be reduced. However, calibrating an aggressor RF circuit such as a power amplifier may involve adjusting for both amplitude and phase shift, due to the resonant circuit in a power amplifier. The description below explores this phenomenon by first modeling transformer coupling between an amplifier circuit and an antenna to understand how to adjust the imbalances and then extends this idea to coupling between an aggressor circuit (e.g., a 2G PA) and a victim circuit (e.g., a 5G DA).

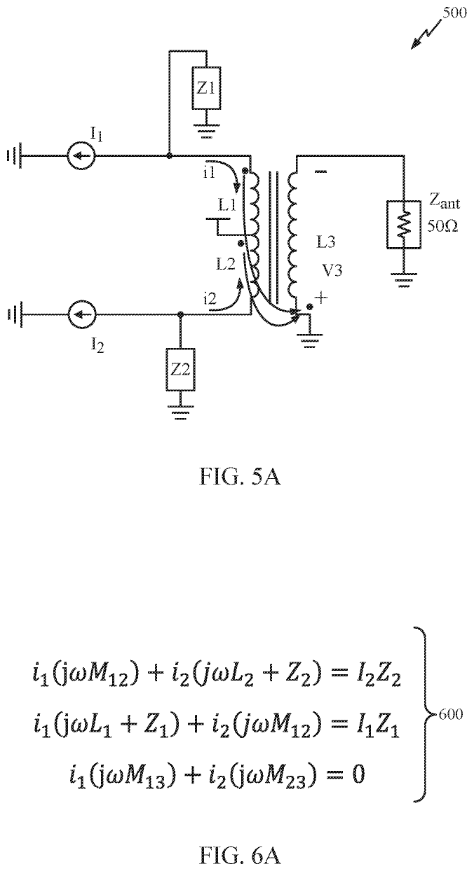

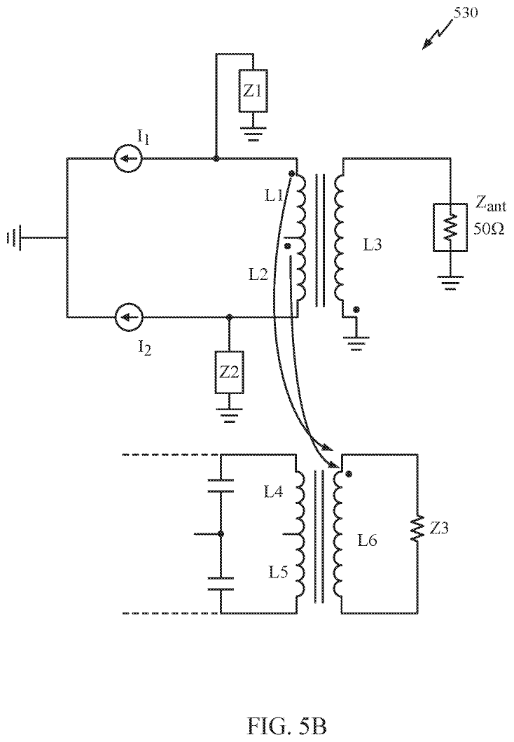

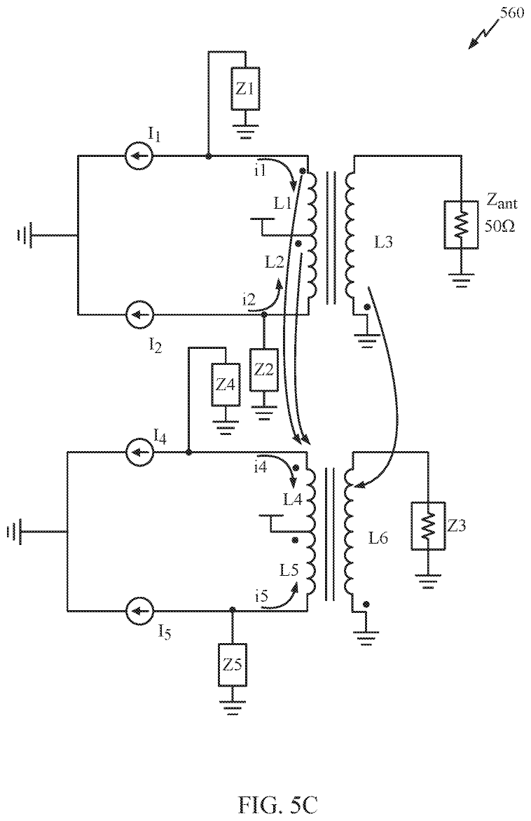

FIG. 5A is an example circuit model 500 of transformer coupling between a transmit output stage circuit (e.g., a DA or PA, such as PA 456) and an antenna (e.g., antenna 460), in accordance with certain aspects of the present disclosure. The transformer coupling in the circuit model 500 may represent the transformer 458 in FIG. 4B, for example. Although the implementation of the transmit output stage circuit may be differential, the common mode is modeled in the circuit model 500, because it is desirable to cancel the common-mode signal out of the transformer. Thus, the circuit model 500 includes a first self-inductance L1 representing a portion of the tapped primary coil (e.g., primary coil 464), a second self-inductance L2 representing a remaining portion of the tapped primary coil, and a third self-inductance L3 representing the secondary coil (e.g., secondary coil 466). The circuit model also includes a first mutual inductance M12 between the two portions of the primary coil, a second mutual inductance M13 between the portion of the primary coil and the secondary coil, and a third mutual inductance M23 between the remaining portion of the primary coil and the secondary coil. The positive output of the transmit output stage circuit is associated with a current source I1 and an impedance Z1, whereas the negative output of the transmit output stage circuit is associated with a current source I2 and an impedance Z2. The antenna is modeled with an impedance Zant (e.g., having a characteristic impedance of 50 Ω).

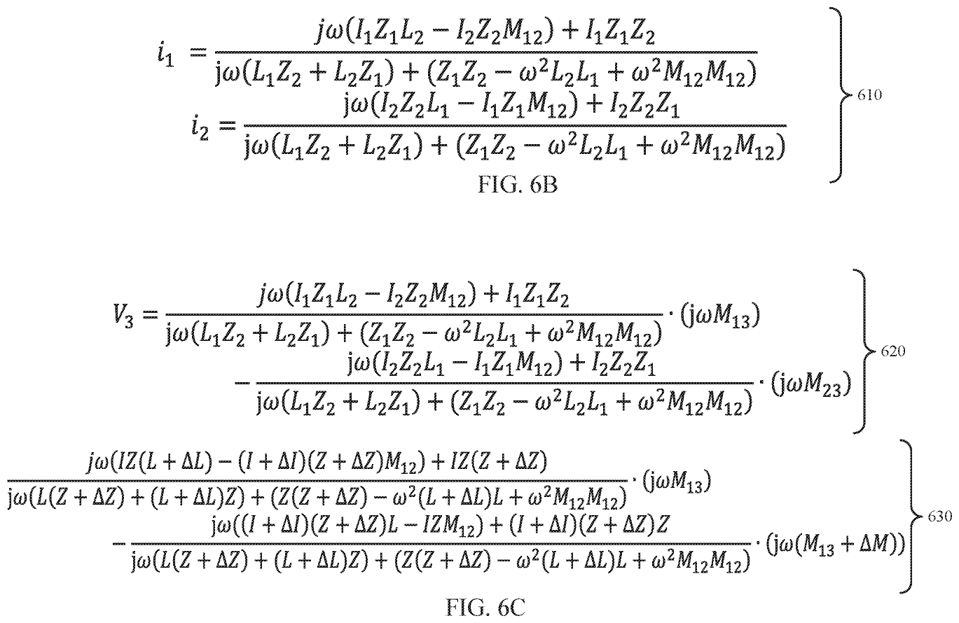

Assuming none of these variables are equal (e.g., Z₁≠Z₂, I₁≠I₂, L₁≠L₂, and M₁₃≠M₂₃), FIG. 6A is a system of equations 600 for the circuit model 500 of FIG. 5A, in accordance with certain aspects of the present disclosure. FIG. 6B illustrates the system of equations 600 of FIG. 6A rewritten in terms of the currents through the primary coil to generate equations 610, in accordance with certain aspects of the present disclosure. In other words, equations 610 represent the solutions to the first two equations in the system of equations 600 for i₁ and i₂. FIG. 6C illustrates an equation 620 for the voltage V₃ across the secondary coil, based on substituting the equations 610 of FIG. 6B for the third equation in the system of equations 600, in accordance with certain aspects of the present disclosure. Equation 630 represents a version of equation 620, substituting Z₁=Z, Z₂=Z+ΔZ, I₁=I, 1₂=I₁=ΔI, L, L₂=L+ΔL, and M₂₃=M₁₃+ΔM.

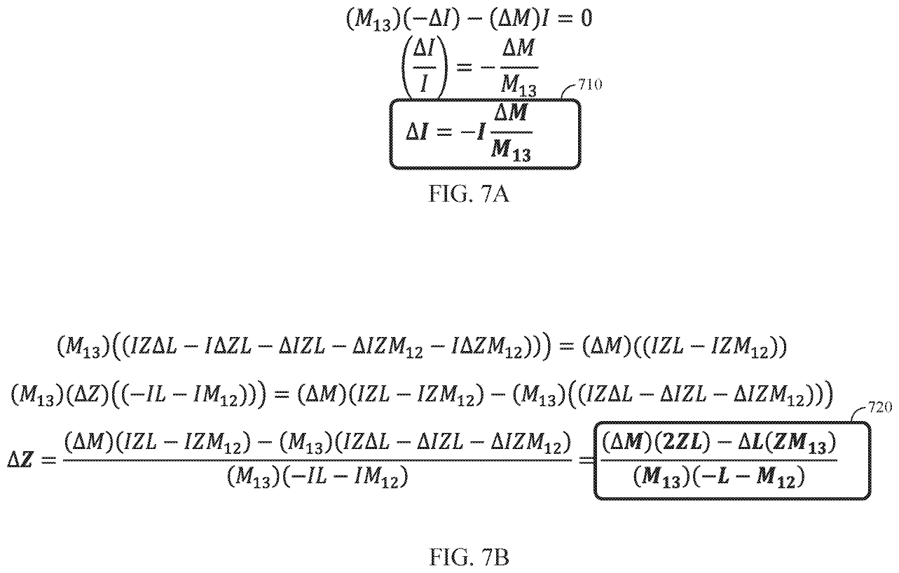

By assuming Z is a real number, solutions for equation 630 can be determined to have V₃=0 (the desired result for no common-mode transformer coupling). FIG. 7A illustrates a solution 710 for the equation 630 of FIG. 6C in terms of a change in current (ΔI), in accordance with certain aspects of the present disclosure. FIG. 7B illustrates a solution 720 for the equation 630 of FIG. 6C in terms of a change in impedance, (ΔZ) in accordance with certain aspects of the present disclosure.

Current adjustment (ΔI) may be implemented in a transmit output stage circuit by controlling the transconductance (gₘ) of a differential pair of transistors, either separately or together. Controlling the transconductance may be accomplished using any of various suitable techniques, including: (1) adjusting a bias voltage at the gate of each of the transistors or (2) selectively coupling a number of transistors in parallel for the transconductance stage (also referred to as changing the “slice offset,” where a slice refers to one replicated copy of the transconductance stage transistor).

Impedance adjustment (ΔZ) may be implemented in a transmit output stage circuit by adjusting the capacitance in an inductance-capacitance (LC) tank circuit (also referred to as a resonant circuit, a tank circuit, or a tuned circuit). The inductance in the LC tank circuit may be provided by the primary coil of the balun, for example. In a differential LC tank circuit, the capacitive elements may be controlled independently or together. Changing the capacitance may be accomplished using any of various suitable techniques, including using tuned capacitive elements or selectively coupling a number of capacitive elements together, in parallel and/or in series, to achieve a desired capacitance value. For example, certain aspects may utilize a switched capacitive array, implemented with a number of branches coupled in parallel, where each branch includes a switch and one or more capacitive element connected in series. By selectively closing and opening various branch switches in the array, different capacitance values may be achieved. For certain aspects, the array may be a binary-weighted capacitance array, in which each branch of the array includes a capacitive element having a capacitance that varies from other branches by a factor of 2. For example, if one branch has a capacitance of C, other branches may capacitances of C/2, C/4, etc. As used herein, a “capacitive element” generally refers to an electrical component having a capacitance property, which may be implemented by a capacitor, a transistor, or any of various other suitable components.

Although this idea has been explored above for transformer coupling between a transmit output stage circuit and an antenna to reduce the common-mode signal reaching the secondary coil of the transformer, the idea can be applied to electromagnetic (EM) coupling between an aggressor transmit output stage circuit and a victim circuit, as illustrated in the circuit model 530 of FIG. 5B. For example, the aggressor transmit output stage circuit may be the 2G PA 456 and transformer 458, whereas the victim circuit may be the 5G PA 476 and transformer 478 in FIG. 4B. In the circuit model 530, secondary coil L6 sees coupling tones from both the L1 and L2 coils. By adjusting the current and/or the impedance in the aggressor transmit output stage circuit, the common-mode signal (e.g., a second-order harmonic signal) output by the transmit output stage circuit and reaching the victim circuit can be reduced.

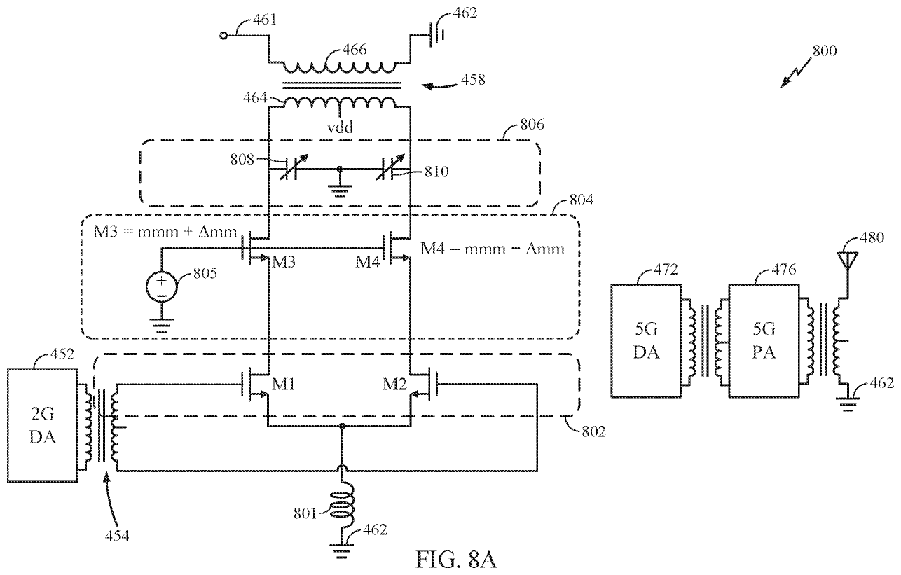

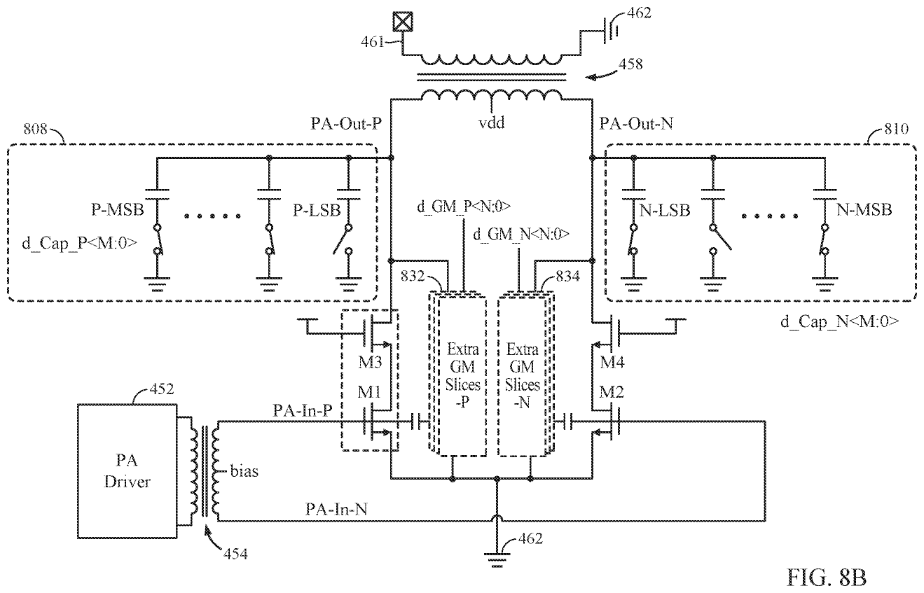

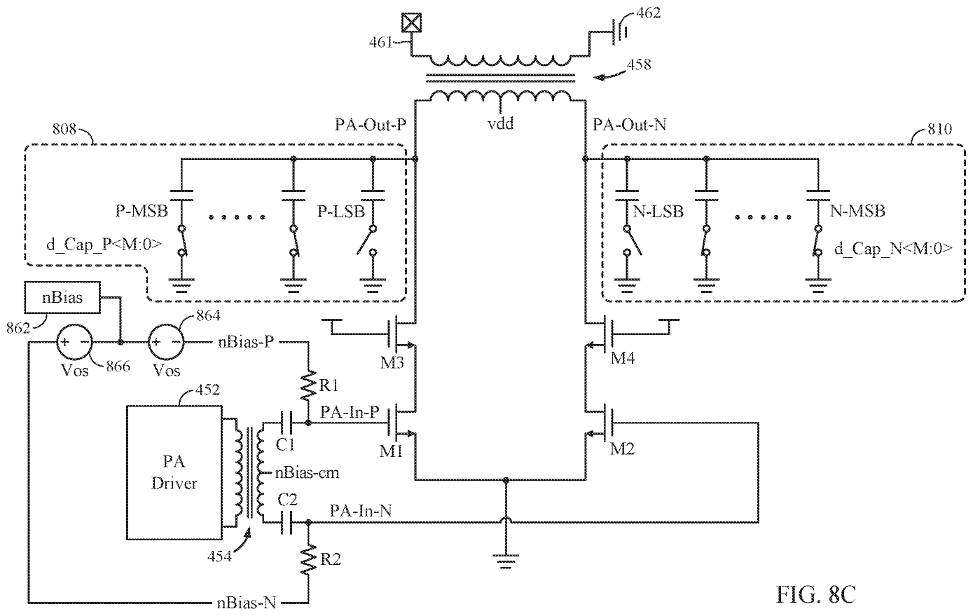

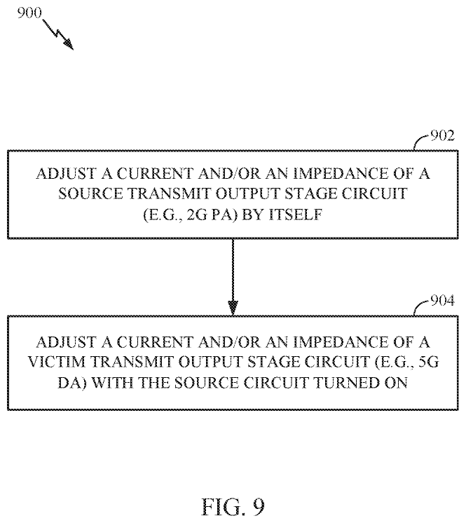

FIG. 8A is a schematic diagram of an example transmit output stage circuit 800 capable of current adjustment (ΔI) and/or impedance adjustment (ΔZ), in accordance with certain aspects of the present disclosure. The transmit output stage circuit 800 is an amplifier circuit, which may represent a driver amplifier or a power amplifier and may be used in implementing the RFFE circuit 450 of FIG. 4B, for example.

The transmit output stage circuit 800 includes an adjustable transconductance stage (comprising an input stage 802 and a cascode stage 804 coupled to the input stage) and an adjustable impedance stage 806 coupled to the adjustable transconductance stage. The transmit output stage circuit 800 may also include an impedance 801 coupled between the input stage 802 and the reference potential node 462. The impedance 801 may be implemented with an inductive element or a resistive element, for example.

The input stage 802 may include a differential pair of representative transistors M1 and M2. The gate of representative transistor M1 may be coupled to one end of the secondary coil in the transformer 454, whereas the gate of representative transistor M2 may be coupled to the other end of the secondary coil in the transformer 454, as illustrated in FIG. 8A. The sources of representative transistors M1 and M2 may be coupled to the impedance 801, whereas the drains of transistors M1 and M2 may be coupled to the cascode stage 804. As illustrated in FIG. 8A, each of the representative transistors M1 and M2 may be configured as a common-source amplifier. Thus, the input stage 802 may amplify the differential signal received at the gates of representative transistors M1 and M2 and output this amplified differential signal to the drains of transistors M1 and M2. Representative transistor M1 may be considered arbitrarily as the positive side of the transmit output stage circuit 800, whereas representative transistor M2 may be arbitrarily considered as the negative side of the transmit output stage circuit 800.

The cascode stage 804 may include representative transistors M3 and M4. The sources of representative transistors M3 and M4 may be coupled to the drains of transistors M1 and M2, and the drains of representative transistors M3 and M4 may be coupled to the adjustable impedance stage 806. Thus, the representative transistor M3 may be coupled in cascode to the transistor Ml, and the representative transistor M4 may be coupled in cascode to the transistor M2. The gates of representative transistors M3 and M4 may be coupled to a biasing circuit 805 (e.g., implemented by a voltage source, as depicted). Each of the representative transistors M3 and M4 may be configured as a common-gate amplifier, as illustrated in FIG. 8A. Therefore, representative transistors M3 and M4 may each form a cascode amplifier with representative transistors M1 and M2, respectively, thereby forming a differential cascode amplifier.

For certain aspects as illustrated in FIG. 8B, each cascoded pair of representative transistors M1/M3 and M2/M4 may represent a plurality of cascoded pairs of transistors coupled in parallel, where each cascoded pair (each branch of the parallel array) represents a slice. For example, 256 copies of the same cascoded transistor pair may be coupled in parallel to implement representative transistor pair M1/M3, (as in transconductance slices 832, labeled “Extra GM Slices-P”), and another 256 copies of the same cascoded transistor pair may be coupled in parallel to implement representative transistor pair M2/M4 (as in transconductance slices 834, labeled “Extra GM Slices-N”). The gate bias voltage of each of these transistors may be either on (e.g., set to a predefined bias voltage) or off (e.g., set to 0 V), so that a desired portion of the cascoded transistor pairs in the parallel array will be enabled, in an effort to control the total transconductance of the array. In this manner, a number of transistors (e.g., from 1 to 256) may be selectively enabled for representative transistors M1 and M3 to change the transconductance on the positive side of the transmit output stage circuit 800 (e.g., in transconductance slices 832), and another number of transistors (e.g., from 1 to 256) may be selectively enabled for representative transistors M2 and M4 to change the transconductance on the negative side of the transmit output stage circuit 800 (e.g., in transconductance slices 834). The numbers of enabled transistors for representative transistor pairs M1/M3 and M2/M4 may be selected independently or jointly. In other words, the number of enabled transistors selected for representative transistor pair M2/M4 may or may not match the number of enabled transistors selected for representative transistor pair M1/M3. For certain aspects, a predetermined number of enabled transistors mmm (e.g., 168) may be selected, and a slice offset (Amm) may be designated (e.g., during calibration) for varying the predetermined number for both representative transistor pairs M1/M3 and M2/M4. For example, the number of enabled transistors for representative transistor pair M1/M3 may be mmm+Δmm (e.g., 178 for mmm=168 and Δmm=10), whereas the number of enabled transistors for representative transistor pair M2/M4 may be mmm−Δmm (e.g., 158 for mmm=168 and Δmm=10).

For other aspects, a bias voltage at each of the gates of representative transistors M1 and M2 may be adjusted to effectively change the transconductance of each of the representative transistor pairs M1/M3 and M2/M4. In this manner, the transconductances of the representative transistor pairs M1/M3 and M2/M4 may be independently controlled. For example, FIG. 8C illustrates an example adjustable bias circuit coupled to the input stage 802. The adjustable bias circuit comprises an adjustable bias voltage 862, voltage offsets 864 and 866, resistors R1 and R2, and capacitors C1 and C2. Other bias voltages may be applied to the gates of representative transistors M3 and M4, and these bias voltages may be variable or fixed and adjusted or set independently. For other aspects as illustrated in FIG. 8A, a single bias voltage (e.g., provided by biasing circuit 805) may be provided to the gates of representative transistors M3 and M4, such that the bias voltage may be adjusted or set jointly. For certain aspects, both the bias voltage(s) and the number of transistors may be used to adjust the transconductances of the representative transistor pairs Ml/M3 and M2/M4.

The adjustable impedance stage 806 may include a first adjustable capacitance stage 808 and a second adjustable capacitance stage 810. The first adjustable capacitance stage 808 may be coupled between the positive side of the transmit output stage circuit 800 and the reference potential node 462. The second adjustable capacitance stage 810 may be coupled between the negative side of the transmit output stage circuit 800 and the reference potential node 462. The first and second adjustable capacitance stages 808, 810 may be controlled together or independently, in an effort to adjust the impedance of the LC tank circuit formed by the primary coil 464 of the transformer 458 and the adjustable capacitance stages 808, 810. For certain aspects, each of the first and second adjustable capacitance stages 808, 810 may be implemented by one or more tuned capacitive elements. For other aspects, each of the first and second adjustable capacitance stages 808, 810 may be implemented by selectively coupling a number of capacitive elements together, in parallel and/or in series combinations, to achieve a desired capacitance value. For example, as illustrated in FIGS. 8B and 8C, certain aspects may utilize a switched capacitive array, implemented with a number of branches coupled in parallel, where each branch includes a switch and one or more capacitive element connected in series with the switch. By selectively closing and opening various branch switches in the switched capacitance array, different capacitance values may be achieved. For certain aspects, the array may be a binary-weighted capacitance array, as described above.

In some cases, the current and/or the impedance may also be adjusted in the victim transmit output stage circuit. FIG. 5C is an example circuit model 560 of adjusting current and impedance in the victim circuit of FIG. 5B, in accordance with certain aspects of the present disclosure. Such adjustment may be beneficial if common-mode currents 14 and IS provide enough second-order harmonic signal such that currents I4 and/or I5 can be used as an effective adjustment knob. Otherwise, a capacitor bank including adjustable capacitance stages (not shown) may be used as an effective tuning knob. However, since ground coupling may be a worse offender than EM coupling, adjusting currents I4 and I5 may likely be effective in reducing second-order harmonics at the victim circuit.

FIG. 9 is a flow diagram of example operations 900 for calibrating an RFFE circuit, in accordance with certain aspects of the present disclosure. The operations 900 may be performed by and/or for an RFFE circuit, such as the RFFE circuit of FIG. 8A.

The operations 900 may begin, at block 902, by adjusting a current (e.g., by adjusting a transconductance) and/or an impedance of a source transmit output stage circuit (e.g., 2G PA 456 or 2G PA 412) by itself. These adjustments may be made to minimize, or at least reduce, the second-order harmonic signal output by the source circuit. The adjustment(s) may involve utilizing the adjustable transconductance stage and/or the adjustable impedance stage 806 in the source circuit as described above. More particularly, making the adjustment(s) may entail sweeping through the transconductance adjustments and/or the capacitance adjustments until a minimum value or a value below a threshold is found for the second-order harmonic signal. As described above, the transconductance and/or capacitance sweeping may be done independently or collectively for components in a differential circuit.

At block 904, the operations 900 may continue by adjusting a current (e.g., by adjusting a transconductance) and/or an impedance of a victim transmit output stage circuit (e.g., 5G PA 476) with the source circuit turned on, using the adjustment(s) to the source circuit from block 902. The adjustment(s) to the victim circuit may involve utilizing the adjustable transconductance stage and/or the adjustable impedance stage 806 in the victim circuit, as described above. These adjustments to the victim circuit may be made to minimize, or at least reduce, the second-order harmonic signal coupled into the victim circuit, from the source circuit. More specifically, making the adjustment(s) may entail sweeping through the transconductance adjustments and/or the capacitance adjustments until a minimum value or a value below a threshold is found for the second-order harmonic signal coupled into the victim circuit. As described above, the transconductance and/or capacitance sweeping may be done independently or collectively for components in a differential circuit.

According to certain aspects, the calibration operations 900 may also involve checking if the adjustment values associated with either or both the source and victim circuits need to be tweaked if multiple amplifier circuits (e.g., the 2G DA 452, the 2G DA 406, and/or the 2G pPA 410) in the source transmit path are activated.

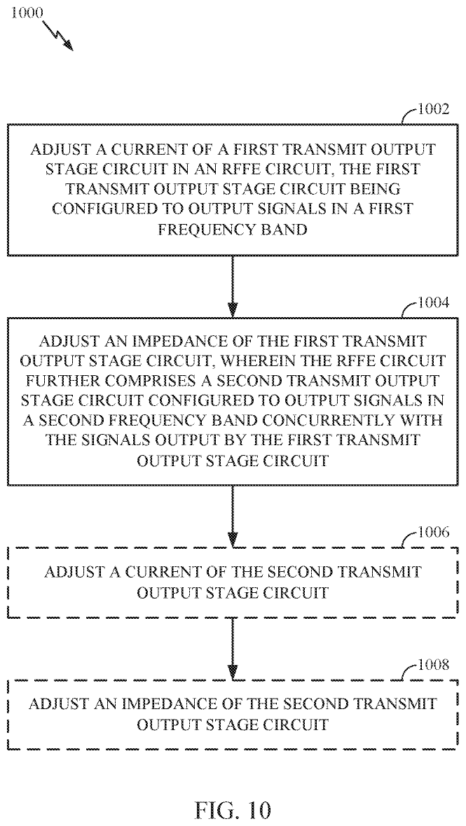

FIG. 10 is a flow diagram of example operations 1000 for adjusting an RFFE circuit capable of simultaneous multi-band transmission, in accordance with certain aspects of the present disclosure. The operations 1000 may be performed by and/or for an RFFE circuit, such as the RFFE circuit of FIG. 8A.

The operations 1000 may begin, at block 1002, by adjusting a current (e.g., by adjusting a transconductance) of a first transmit output stage circuit (e.g., transmit output stage circuit 800) in the RFFE circuit, where the first transmit output stage circuit is configured to output signals in a first frequency band. At block 1004, the operations 1000 may continue by adjusting an impedance of the first transmit output stage circuit. The RFFE circuit further comprises a second transmit output stage circuit (e.g., similar to transmit output stage circuit 800) configured to output signals in a second frequency band concurrently with the signals output by the first transmit output stage circuit.

According to certain aspects, adjusting the current (e.g., transconductance) of the first transmit output stage circuit at block 1002 includes changing a number of transistors selectively coupled in parallel to adjust a transconductance (gₘ) in the first transmit output stage circuit and to reduce an amplitude of a second-order harmonic signal output by the first transmit output stage circuit.

According to certain aspects, adjusting the current (e.g., transconductance) of the first transmit output stage circuit at block 1002 involves changing a bias voltage at a control terminal of a transistor in the first transmit output stage circuit to adjust a transconductance in the first transmit output stage circuit and to reduce an amplitude of a second-order harmonic signal output by the first transmit output stage circuit.

According to certain aspects, adjusting the impedance of the first transmit output stage circuit at block 1004 includes changing at least one of: (1) a number of capacitive elements selectively coupled in parallel or (2) a capacitance of a capacitive element, to reduce an amplitude of a second-order harmonic signal output by the first transmit output stage circuit.

According to certain aspects, the first frequency band is a nominal 2.4 GHz band. For certain aspects, the second frequency band is a nominal 5 GHz band.

According to certain aspects, the first frequency band has a second harmonic that falls in a bandwidth of the second frequency band. For certain aspects, at least one of adjusting the current (e.g., transconductance) or adjusting the impedance of the first transmit output stage circuit reduces an amplitude of the second harmonic appearing in the second transmit output stage circuit.

At optional block 1006, the operations 1000 may further entail adjusting a current (e.g., by adjusting a transconductance) of the second transmit output stage circuit. According to certain aspects, adjusting the current of the second transmit output stage circuit at optional block 1006 includes changing a number of transistors selectively coupled in parallel to adjust a transconductance (gₘ) in the second transmit output stage circuit and to reduce an amplitude of a second-order harmonic signal output by the first transmit output stage circuit and coupled into the second transmit output stage circuit. For other aspects, adjusting the current of the second transmit output stage circuit at optional block 1006 involves changing a bias voltage at a control terminal of a transistor in the second transmit output stage circuit to adjust a transconductance in the second transmit output stage circuit and to reduce an amplitude of a second-order harmonic signal output by the first transmit output stage circuit and coupled into the second transmit output stage circuit.

At optional block 1008, the operations 1000 may further involve adjusting an impedance of the second transmit output stage circuit. According to certain aspects, adjusting the impedance of the second transmit output stage circuit at optional block 1008 entails changing at least one of: (1) a number of capacitive elements selectively coupled in parallel or (2) a capacitance of a capacitive element, in the second transmit output stage circuit to reduce an amplitude of a second-order harmonic signal output by the first transmit output stage circuit and coupled into the second transmit output stage circuit.

Certain aspects of the present disclosure provide an RFFE circuit (e.g., RFFE circuit 450). The RFFE circuit generally includes a first transmit output stage circuit (e.g., transmit output stage circuit 800) configured to output signals in a first frequency band and a second transmit output stage circuit (e.g., PA 476) configured to output signals in a second frequency band. The first transmit output stage circuit generally includes a first adjustable transconductance stage comprising an input stage (e.g., input stage 802) and a cascode stage (e.g., cascode stage 804) coupled to the input stage, and a first adjustable impedance stage (e.g., adjustable impedance stage 806) coupled to the first adjustable transconductance stage.

According to certain aspects, the second transmit output stage circuit is configured to output the signals in the second frequency band concurrently with the signals in the first frequency band output by the first transmit output stage circuit.

According to certain aspects, the input stage includes a first set of transistors (e.g., representative transistor M1) on a positive side of the first transmit output stage circuit, and a second set of transistors (e.g., representative transistor M2) on a negative side of the first transmit output stage circuit. For certain aspects, the first cascode stage generally includes: (1) a third set of transistors (e.g., representative transistor M3) coupled in cascode to the first set of transistors; and (2) a fourth set of transistors (e.g., representative transistor M4) coupled in cascode to the second set of transistors in the input stage. For certain aspects, a number of cascoded transistor pairs in the first and third sets is selectively enabled to control a transconductance (gₘ) of the positive side. In this case, a number of cascoded transistors in the second and fourth sets is selectively enabled to control a transconductance of the negative side. For certain aspects, a first bias voltage provided to at least one control terminal (e.g., the gate) of the first set of transistors is configured to control a transconductance of the positive side. In this case, a second bias voltage may be provided to at least one control terminal of the second set of transistors and may be configured to control a transconductance of the negative side. The first bias voltage may be the same as or different from the second bias voltage. For certain aspects, the first adjustable impedance stage generally includes: (1) a first adjustable capacitance stage (e.g., stage 808) coupled to the positive side of the first transmit output stage circuit; and (2) a second adjustable capacitance stage (e.g., stage 810) coupled to the negative side of the first transmit output stage circuit. In this case, the first adjustable capacitance stage may include a first set of capacitive elements selectively coupled to the positive side, and/or the second adjustable capacitance stage may include a second set of capacitive elements selectively coupled to the negative side of the differential pair of transistors in the first input stage. For certain aspects, at least one of the first adjustable capacitance stage or the second adjustable capacitance stage comprises a binary-weighted capacitance array. For certain aspects, the first adjustable capacitance stage is independently adjustable from the second adjustable capacitance stage. For other aspects, the first and second adjustable capacitance stages are jointly adjustable.

According to certain aspects, the second transmit output stage circuit generally includes a second adjustable transconductance stage (e.g., similar to the first adjustable transconductance stage) and a second adjustable impedance stage (e.g., similar to adjustable impedance stage 806) coupled to the second adjustable transconductance stage. For example, the second adjustable transconductance stage may include an input stage (e.g., similar to input stage 802) and a cascode stage (e.g., similar to cascode stage 804) coupled to the input stage. For certain aspects, the first frequency band has a second harmonic that falls in a bandwidth of the second frequency band. In this case, at least one of the first adjustable impedance stage, the second adjustable impedance stage, the first adjustable transconductance stage, or the second adjustable transconductance stage may be configured for adjustment to reduce an amplitude of the second harmonic appearing in the second transmit output stage circuit.

According to certain aspects, the first frequency band has a second harmonic that falls in a bandwidth of the second frequency band. For certain aspects, at least one of the first adjustable impedance stage or the first adjustable transconductance stage is configured for adjustment to reduce an amplitude of the second harmonic appearing in the second transmit output stage circuit.

According to certain aspects, the first frequency band is a nominal 2.4 GHz band. For certain aspects, the second frequency band is a nominal 5 GHz band.

According to certain aspects, the RFFE circuit further includes a radio frequency signal node (e.g., RF signal node 461 coupled to antenna 460) and a balun (e.g., transformer 458) having a primary coil (e.g., primary coil 464) and a secondary coil (e.g., secondary coil 466). In this case, the primary coil may be coupled to the first adjustable impedance stage, and/or the secondary coil may be coupled between the radio frequency signal node and a reference potential node (e.g., node 462, which may be electrical ground) for the RFFE circuit.

The various operations of methods described above may be performed by any suitable means capable of performing the corresponding functions. The means may include various hardware and/or software component(s) and/or module(s), including, but not limited to a circuit, an integrated circuit (IC), an application-specific integrated circuit (ASIC), or processor. Generally, where there are operations illustrated in figures, those operations may have corresponding counterpart means-plus-function components with similar numbering.

For example, means for transmitting may comprise a transmitter (e.g., the transceiver/front end 254 of the user terminal 120 depicted in FIG. 2, the transceiver/front end 222 of the access point 110 shown in FIG. 2, or the transceiver/front end 300 illustrated in FIG. 3) and/or an antenna (e.g., the antennas 252ma through 252mu of the user terminal 120m portrayed in FIG. 2, the antennas 224a through 224ap of the access point 110 illustrated in FIG. 2, or the antenna 303 of the transceiver/front end 300 depicted in FIG. 3). Means for receiving may comprise a receiver (e.g., the transceiver/front end 254 of the user terminal 120 depicted in FIG. 2, the transceiver/front end 222 of the access point 110 shown in FIG. 2, or the transceiver/front end 300 illustrated in FIG. 3) and/or an antenna (e.g., the antennas 252ma through 252mu of the user terminal 120m portrayed in FIG. 2, the antennas 224a through 224ap of the access point 110 illustrated in FIG. 2, or the antenna 303 of the transceiver/front end 300 depicted in FIG. 3). Means for processing, means for determining, and means for operating may comprise a processing system, which may include one or more processors (e.g., the TX data processor 210, the RX data processor 242, and/or the controller 230 of the access point 110 shown in FIG. 2, or the RX data processor 270, the TX data processor 288, and/or the controller 280 of the user terminal 120 illustrated in FIG. 2). First means for outputting signals in a first frequency band may include a transmit output stage circuit (e.g., the transmit output stage circuit 800 of FIG. 8A). Means for adjusting a current (e.g., a transconductance) may include an adjustable transconductance stage (e.g., the input stage 802 and cascode stage 804 of FIG. 8). Means for adjusting an impedance may include an adjustable impedance stage (e.g., the adjustable impedance stage 806 of FIG. 8A).

As used herein, the term “determining” encompasses a wide variety of actions. For example, “determining” may include calculating, computing, processing, deriving, investigating, looking up (e.g., looking up in a table, a database, or another data structure), ascertaining, and the like. Also, “determining” may include receiving (e.g., receiving information), accessing (e.g., accessing data in a memory), and the like. Also, “determining” may include resolving, selecting, choosing, establishing, and the like.

As used herein, a phrase referring to “at least one of” a list of items refers to any combination of those items, including single members. As an example, “at least one of a, b, or c” is intended to cover: a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

The various illustrative logical blocks, modules, and circuits described in connection with the present disclosure may be implemented or performed with a general purpose processor, a digital signal processor (DSP), an ASIC, a field programmable gate array (FPGA) or other programmable logic device (PLD), discrete gate or transistor logic, discrete hardware components, or any combination thereof designed to perform the functions described herein. A general-purpose processor may be a microprocessor, but in the alternative, the processor may be any commercially available processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The methods disclosed herein comprise one or more steps or actions for achieving the described method. The method steps and/or actions may be interchanged with one another without departing from the scope of the claims. In other words, unless a specific order of steps or actions is specified, the order and/or use of specific steps and/or actions may be modified without departing from the scope of the claims.

The functions described may be implemented in hardware, software, firmware, or any combination thereof. If implemented in hardware, an example hardware configuration may comprise a processing system in a wireless node. The processing system may be implemented with a bus architecture. The bus may include any number of interconnecting buses and bridges depending on the specific application of the processing system and the overall design constraints. The bus may link together various circuits including a processor, machine-readable media, and a bus interface. The bus interface may be used to connect a network adapter, among other things, to the processing system via the bus. The network adapter may be used to implement the signal processing functions of the physical (PHY) layer. In the case of a user terminal, a user interface (e.g., keypad, display, mouse, joystick, etc.) may also be connected to the bus. The bus may also link various other circuits such as timing sources, peripherals, voltage regulators, power management circuits, and the like, which are well known in the art, and therefore, will not be described any further.

The processing system may be configured as a general-purpose processing system with one or more microprocessors providing the processor functionality and external memory providing at least a portion of the machine-readable media, all linked together with other supporting circuitry through an external bus architecture. Alternatively, the processing system may be implemented with an ASIC with the processor, the bus interface, the user interface (in the case of an access terminal), supporting circuitry, and at least a portion of the machine-readable media integrated into a single chip, or with one or more FPGAs, PLDs, controllers, state machines, gated logic, discrete hardware components, or any other suitable circuitry, or any combination of circuits that can perform the various functionality described throughout this disclosure. Those skilled in the art will recognize how best to implement the described functionality for the processing system depending on the particular application and the overall design constraints imposed on the overall system.

It is to be understood that the claims are not limited to the precise configuration and components illustrated above. Various modifications, changes, and variations may be made in the arrangement, operation, and details of the methods and apparatus described above without departing from the scope of the claims.

What is claimed is:

1. A radio frequency front-end (RFFE) circuit comprising:
a first transmit output stage circuit configured to output signals in a first frequency band, the first transmit output stage circuit comprising:
a first adjustable transconductance stage comprising an input stage and a cascode stage coupled to the input stage; and
a first adjustable impedance stage coupled to the first adjustable transconductance stage; and
a second transmit output stage circuit configured to output signals in a second frequency band.

2. The RFFE circuit of claim 1, wherein the second transmit output stage circuit is configured to output the signals in the second frequency band concurrently with the signals in the first frequency band output by the first transmit output stage circuit.

3. The RFFE circuit of claim 1, wherein the input stage comprises:
a first set of transistors on a positive side of the first transmit output stage circuit; and
a second set of transistors on a negative side of the first transmit output stage circuit.

4. The RFFE circuit of claim 3, wherein the cascode stage comprises:
a third set of transistors coupled in cascode to the first set of transistors on the positive side of the first transmit output stage circuit; and
a fourth set of transistors coupled in cascode to the second set of transistors on the negative side of the first transmit output stage circuit.

5. The RFFE circuit of claim 4, wherein:
a number of cascoded transistor pairs in the first and third sets of transistors is selectively enabled to control a transconductance of the positive side of the first transmit output stage circuit; and
a number of cascoded transistor pairs in the second and fourth sets of transistors is selectively enabled to control a transconductance of the negative side of the first transmit output stage circuit.

6. The RFFE circuit of claim 3, wherein:
a first bias voltage provided to at least one control terminal of the first set of transistors is configured to control a transconductance of the positive side of the first transmit output stage circuit; and
a second bias voltage provided to at least one control terminal of the second set of transistors is configured to control a transconductance of the negative side of the first transmit output stage circuit.

7. The RFFE circuit of claim 3, wherein the first adjustable impedance stage comprises:
a first adjustable capacitance stage coupled to the positive side of the first transmit output stage circuit; and
a second adjustable capacitance stage coupled to the negative side of the first transmit output stage circuit.

8. The RFFE circuit of claim 7, wherein:
the first adjustable capacitance stage comprises a first set of capacitive elements selectively coupled to the positive side of the first transmit output stage circuit; and
the second adjustable capacitance stage comprises a second set of capacitive elements selectively coupled to the negative side of the first transmit output stage circuit.

9. The RFFE circuit of claim 7, wherein at least one of the first adjustable capacitance stage or the second adjustable capacitance stage comprises a binary-weighted capacitance array.

10. The RFFE circuit of claim 7, wherein the first adjustable capacitance stage is independently adjustable from the second adjustable capacitance stage.

11. The RFFE circuit of claim 1, wherein the second transmit output stage circuit comprises:
a second adjustable transconductance stage; and
a second adjustable impedance stage coupled to the second adjustable transconductance stage.

12. The RFFE circuit of claim 11, wherein the first frequency band has a second harmonic that falls in a bandwidth of the second frequency band and wherein at least one of the first adjustable impedance stage, the second adjustable impedance stage, the first adjustable transconductance stage, or the second adjustable transconductance stage is configured for adjustment to reduce an amplitude of the second harmonic appearing in the second transmit output stage circuit.

13. The RFFE circuit of claim 1, wherein the first frequency band has a second harmonic that falls in a bandwidth of the second frequency band and wherein at least one of the first adjustable impedance stage or the first adjustable transconductance stage is configured for adjustment to reduce an amplitude of the second harmonic appearing in the second transmit output stage circuit.

14. The RFFE circuit of claim 1, wherein the first frequency band is a nominal 2.4 GHz band and wherein the second frequency band is a nominal 5 GHz band.

15. The RFFE circuit of claim 1, further comprising:
a radio frequency signal node; and
a balun having a primary coil and a secondary coil, wherein the primary coil is coupled to the first adjustable impedance stage and wherein the secondary coil is coupled between the radio frequency signal node and a reference potential node for the RFFE circuit.

16. A method of adjusting a radio frequency front-end (RFFE) circuit capable of simultaneous multi-band transmission, the method comprising:
adjusting a transconductance of a first transmit output stage circuit in the RFFE circuit, the first transmit output stage circuit being configured to output signals in a first frequency band; and
adjusting an impedance of the first transmit output stage circuit, wherein the RFFE circuit further comprises a second transmit output stage circuit configured to output signals in a second frequency band concurrently with the signals output by the first transmit output stage circuit.

17. The method of claim 16, further comprising at least one of:
adjusting a transconductance of the second transmit output stage circuit; or
adjusting an impedance of the second transmit output stage circuit.

18. The method of claim 16, wherein adjusting the transconductance of the first transmit output stage circuit comprises changing a number of transistors selectively coupled in parallel to reduce an amplitude of a second-order harmonic signal output by the first transmit output stage circuit.

19. The method of claim 16, wherein adjusting the transconductance of the first transmit output stage circuit comprises changing a bias voltage at a control terminal of a transistor in the first transmit output stage circuit to reduce an amplitude of a second-order harmonic signal output by the first transmit output stage circuit.

20. The method of claim 16, wherein adjusting the impedance of the first transmit output stage circuit comprises changing at least one of a number of capacitive elements selectively coupled in parallel or a capacitance of a capacitive element, to reduce an amplitude of a second-order harmonic signal output by the first transmit output stage circuit.
